(19) United States
(12) Patent Application Publication
(10) Pub. No.: US 2014/0131827 A1
(43) Pub. Date: May 15, 2014

(54) AVALANCHE PHOTODIODE AND METHOD OF MANUFACTURE THEREOF

(71) Applicant: Mitsubishi Electric Corporation, Tokyo (JP)

(72) Inventors: Harunaka Yamaguchi, Tokyo (JP); Ryota Takemura, Tokyo (JP)

(21) Appl. No.: 13/944,942

(22) Filed: Jul. 18, 2013

(30) Foreign Application Priority Data
Nov. 13, 2012 (JP) 2012-249457

(51) Int. Cl. H01L 31/107

(52) U.S. Cl. CPC H01L 31/107
USPC 257/438; 438/91

(57) ABSTRACT

An i-type AlInAs avalanche multiplication layer is grown on an n-type InP substrate. A p-type AlInAs electric field reduction layer is grown on the i-type AlInAs avalanche multiplication layer. Transition layers are grown to cover the top surface of the electric field reduction layer. After the covering of the top surface of the electric field reduction layer by the transition layers, the temperature of the growth process is increased and an n⁻-type InGaAs light absorption layer is grown on the transition layer at a temperature higher than the growth temperature of the electric field reduction layer. The growth temperature of the transition layers is lower than that of the n⁻-type InGaAs light absorption layer. The transition layers have higher resistance to surface defects than the electric field reduction layer at temperatures higher than the growth temperature of the electric field reduction layer.

### FIELD OF THE INVENTION

The present invention relates to an avalanche photodiode and a method of manufacture thereof.

### BACKGROUND ART

Avalanche photodiodes having an avalanche multiplication layer, an electric field buffer layer of p-type semiconductor, and a light absorption layer of p-type semiconductor have been known, as disclosed, e.g., in Japanese Laid-Open Patent Publication No. 2004-31707. In the prior art avalanche photodiode disclosed in this publication, the electric field buffer layer is made of p-type semiconductor material and a bandgap grading layer is interposed between the electric field buffer layer and the light absorption layer in order to improve the characteristics of the photodiode. The material compositions of the layers of the avalanche photodiode as specified in the publication are as follows: the light absorption layer of p-type semiconductor is composed of InGaAsP mixed crystal, the bandgap grading layer is composed of InGaAsP mixed crystal or InGaAlAs mixed crystal, and the avalanche multiplication layer and/or the electric field buffer layer of p-type semiconductor is composed of InP or InAlAs mixed crystal.

Other prior art includes Published Japanese Translation of PCT Application No. 2005-516414.

It is common practice that the electric field reduction layer of an avalanche photodiode is configured as a doped semiconductor layer. In that case, the crystal growth of the electric field reduction layer is sometimes performed at low temperature so that the layer will have the desired adequate carrier concentration. In contrast, the light absorption layer needs to be grown at relatively high temperature so as to have good crystal quality. That is, the growth temperature of the light absorption layer is higher than that of the electric field reduction layer. Therefore, if the light absorption layer is grown after the growth of the electric field reduction layer in the manufacture of the avalanche photodiode, the temperature of the growth process must be increased when switching from the growth of the electric field reduction layer to that of the light absorption layer. It has been found, however, that this increase in the process temperature causes thermal damage to the surface of the electric field reduction layer, resulting in defects in the interface between the electric field reduction layer and the light absorption layer subsequently formed on the electric field reduction layer.

### SUMMARY OF THE INVENTION

The present invention has been made to solve the above problems. It is, therefore, an object of the present invention to provide an improved avalanche photodiode and a method of manufacture thereof wherein the avalanche photodiode is manufactured while minimizing thermal damage due to an increase in the temperature of the growth process so that the avalanche photodiode has good crystal growth interfaces.

According to one aspect of the present invention, a method of manufacturing an avalanche photodiode includes the steps of: growing a multiplication layer on a semiconductor substrate; growing an electric field reduction layer on the multiplication layer at a first temperature; growing a transition layer at a second temperature so as to cover a top surface of the electric field reduction layer; and growing a light absorption layer on the transition layer. The light absorption layer is grown on the transition layer at a third temperature higher than the first temperature at which the electric field reduction layer is grown after the covering of the top surface of the electric field reduction layer by the transition layer. Wherein, the second temperature at which the transition layer is grown is lower than the third temperature at which the light absorption layer is grown. Wherein, the transition layer is composed of a semiconductor material having higher resistance to surface defects than the electric field reduction layer at temperatures higher than the first temperature at which the electric field reduction layer is grown.

According to other aspect of the present invention, an avalanche photodiode includes: a semiconductor substrate; a multiplication layer; an electric field reduction layer; a transition layer; and a light absorption layer. The multiplication layer is grown on the semiconductor substrate. The electric field reduction layer is grown on the multiplication layer. The transition layer is grown to cover a top surface of the electric field reduction layer. The light absorption layer is grown on the transition layer at a temperature. Wherein, the transition layer has a bandgap intermediate between the bandgap of the electric field reduction layer and the bandgap of the light absorption layer. Wherein, the transition layer is composed of a semiconductor material that grows at a temperature lower than the temperature at which the light absorption layer is grown. Wherein, the transition layer is composed of a semiconductor material having higher resistance to surface defects than the electric field reduction layer at the temperature at which the light absorption layer is grown.

Other and further objects, features and advantages of the invention will appear more fully from the following description.

### BRIEF DESCRIPTION OF THE DRAWINGS

FIG. 1 is a cross-sectional view showing the configuration of an avalanche photodiode 20 in accordance with an embodiment of the present invention.

FIG. 2 is a diagram showing the energy distribution in the conduction and valence bands of the contiguous portions of the AlInAs electric field reduction layer and the InGaAs light absorption layer of a comparative example photodiode.

FIG. 3 is a diagram illustrating features and advantages of the present embodiment.

FIG. 4 is a diagram showing a growth sequence of a comparative example avalanche photodiode having a carbon-doped AlInAs electric field reduction layer.

FIG. 5 is a diagram showing a growth sequence of an avalanche photodiode having a carbon-doped AlInAs electric field reduction layer in accordance with the present embodiment.

FIG. 6 is a flowchart showing a method of manufacturing an avalanche photodiode in accordance with the present embodiment.

### DETAILED DESCRIPTION OF THE PREFERRED EMBODIMENTS

Configuration of Device of Embodiment of the Invention

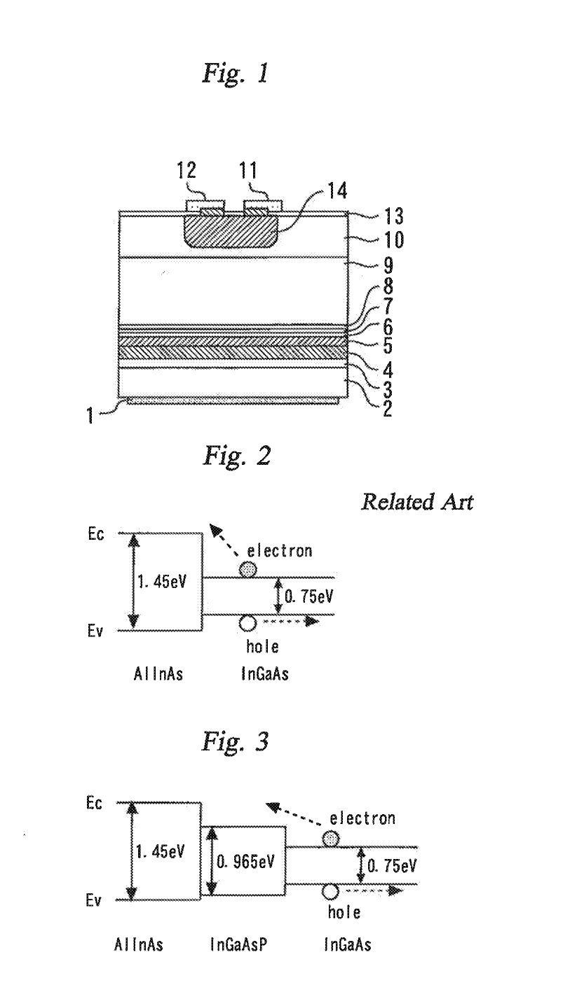

FIG. 1 is a cross-sectional view showing the configuration of an avalanche photodiode 20 in accordance with an embodiment of the present invention. The avalanche photodiode 20 includes an n-type InP substrate 2. An n-type InP buffer layer 3 and an i-type AlInAs avalanche multiplication layer 4 are grown on the n-type InP substrate 2. The n-type InP buffer layer 3 has a carrier concentration of 1×10¹⁸-5×10¹⁸ cm⁻³ and a thickness of 0.1-1 μm. The i-type AlInAs avalanche multiplication layer 4 has a thickness of 0.1-0.5 μm.

A p-type AlInAs electric field reduction layer 5 is grown on the i-type AlInAs avalanche multiplication layer 4. The p-type AlInAs electric field reduction layer 5 is a carbon-doped p-type AlInAs electric field reduction layer having a carrier concentration of 0.5×10¹⁸-1×10¹⁸ cm⁻³ and a thickness of 0.05-0.15 μm. Thus in the present embodiment, the p-type AlInAs electric field reduction layer 5 is made of AlInAs doped with carbon, which has a low diffusivity. This carbon acts as a p-type dopant and diffuses from the p-type AlInAs electric field reduction layer 5 at a reduced rate, as compared to other p-type dopants.

A first n⁻-type InGaAsP transition layer 6, a second n⁻-type InGaAsP transition layer 7, and a third n⁻-type InGaAsP transition layer 8 are grown to cover the entire top surface of the p-type AlInAs electric field reduction layer 5. The first n⁻-type InGaAsP transition layer 6 is a semiconductor layer of n⁻-type In₁₋ₓGaₓAs_{y}P_{1-y} (X=0.024 and y=0.053) having a carrier concentration of 1×10¹⁵-5×10¹⁵cm⁻³ and a thickness of 0.01-0.03 μm. The second n⁻-type InGaAsP transition layer 7 is a semiconductor layer of n⁻-type In₁₋ₓGaₓAs_{y}P_{1-y} (X=0.179 and y=0.391) having a carrier concentration of 1×10¹⁵-5×10¹⁵ cm⁻³ and a thickness of 0.01-0.03 μm. The third n⁻-type InGaAsP transition layer 8 is a semiconductor layer of n⁻-type In₁₋ₓGaₓAs_{y}P_{1-y} (X=0.301 and y=0.652) having a carrier concentration of 1×10¹⁵-5×10¹⁵ cm⁻³ and a thickness of 0.01-0.03 μm.

The first, second, and third transition layers 6, 7, and 8 have bandgaps intermediate between those of the p-type AlInAs electric field reduction layer 5 and an n⁻-type InGaAs light absorption layer 9 (described later). Further, the first, second, and third transition layers 6, 7, and 8 are made of n⁻-type InGaAsP, which is a semiconductor material which grows at a temperature lower than the growth temperature of the n⁻-type InGaAs light absorption layer 9. Further, the semiconductor materials of the first, second, and third transition layers 6, 7, and 8 have higher resistance to surface defects than the material of the p-type AlInAs electric field reduction layer 5 at the temperature at which the n⁻-type InGaAs light absorption layer 9 is grown.

The n⁻-type InGaAs light absorption layer 9 is grown on the third n⁻-type InGaAsP transition layer 8. The n⁻-type InGaAs light absorption layer 9 is an n⁻-type InGaAs light absorption layer having a carrier concentration of 1×10¹⁵-5×10¹⁵ cm⁻³ and a thickness of 1-2 μm.

An n⁻-type InP window layer 10, a p-type InGaAs contact layer 11, a p-electrode 12, and an SiNx surface protection antireflection film 13 are formed above the n⁻-type InGaAs light absorption layer 9. The window layer 10 is an n⁻-type InP window layer having a carrier concentration of 0.01×10¹⁵-0.1×10¹⁵ cm⁻³ and a thickness of 0.5-1 μm. The contact layer 11 is a p-type InGaAs contact layer having a carrier concentration of 1×10¹⁸-5×10¹⁸ cm⁻³ and a thickness of 0.1-0.5 μm.

Operation of Device of Embodiment

The avalanche photodiode 20 of the present embodiment is configured for optical communications and achieves high speed response. In operation, a reverse bias voltage is applied across the avalanche photodiode 20, that is, a positive potential relative to the p-electrode 12 is applied to the n-electrode 1. In this state, light to be detected is directed to enter a p-type conductive region 14 (see FIG. 1) from the p-electrode 12 side of the photodiode 20.

Let it be assumed that the light that has entered the avalanche photodiode 20 is 1.3 μm wavelength light (used for optical communications) or 1.5 μm wavelength light (near-infrared light). In that case, the light is absorbed by the n⁻-type InGaAs light absorption layer 9, generating electron-hole pairs. The electrodes then move toward the n-electrode 1, and the holes move toward the p-electrode 12. When the reverse bias voltage applied across the avalanche photodiode 20 is adequately high, these electrons cause ionization in the i-type AlInAs avalanche multiplication layer 4, generating new electron-hole pairs, which in turn cause other ionization events, thus further increasing the number of electrons and holes, i.e., an avalanche multiplication takes place.

Features and advantages of the avalanche photodiode 20 will be described with reference to FIGS. 2 and 3. FIG. 2 is a diagram showing the energy distribution in the conduction and valence bands of the contiguous portions of the AlInAs electric field reduction layer and the InGaAs light absorption layer of a comparative example photodiode which does not have a transition layer between the electric field reduction layer and the light absorption layer. FIG. 3 is a diagram illustrating features and advantages of the present embodiment by showing the energy distribution in the conduction and valence bands of the contiguous portions of the AlInAs electric field reduction layer and the InGaAs light absorption layer and in the conduction and valance bands of the transition InGaAsP transition layer interposed between the electric field reduction layer and the light absorption layer in an avalanche photodiode of the present embodiment.

As shown in FIG. 2, there are very large differences between the conduction band energy levels and between the valence band energy levels of the contiguous portions of the AlInAs electric field reduction layer and the InGaAs light absorption layer; namely, the conduction band energy difference is 0.70 eV and the valence band energy difference is 0.50 eV. In the avalanche photodiode shown in FIG. 3, however, the InGaAsP transition layer (specifically In₁₋ₓGaₓAs_{y}P_{1-y} transition layer, where x=0.272 and y=0.590) is interposed between the AlInAs electric field reduction layer and the InGaAs light absorption layer. The conduction band energy level of the InGaAsP transition layer is intermediate between those of the AlInAs electric field reduction layer and the InGaAs light absorption layer, and the valence band energy level is also intermediate between those of the AlInAs electric field reduction layer and the InGaAs light absorption layer. This means that the differences in conduction band energy level between the AlInAs electric field reduction layer and the InGaAsP transition layer and between the InGaAs light absorption layer and the InGaAsP transition layer are smaller than that between the AlInAs electric field reduction layer and the InGaAs light absorption layer. This reduces pile-up of carriers generated in the avalanche photodiode when the photodiode is illuminated with light, allowing the avalanche photodiode to achieve higher speed response to light.

Particularly, the avalanche photodiode 20 of the present embodiment has three transition layers between the electric field reduction layer and the light absorption layer, and the compositions of these transition layers are suitably adjusted. It should be noted that the bandgap of an InGaAsP transition layer can be changed relatively freely by changing the mole fractions of In, Ga, As, and P. Further, the carrier pile-up can be further reduced by increasing the number of transition layers interposed between the electric field reduction layer and the light absorption layer. Further, when the bandgap of the InGaAsP transition layer is wider than a certain width, the valence band energy level of the InGaAsP transition layer is lower than that of the AlInAs electric field reduction layer. This prevents holes generated in the light absorption layer from reaching the AlInAs multiplication layer, making it possible to reduce dark current.

Manufacturing Method of Embodiment

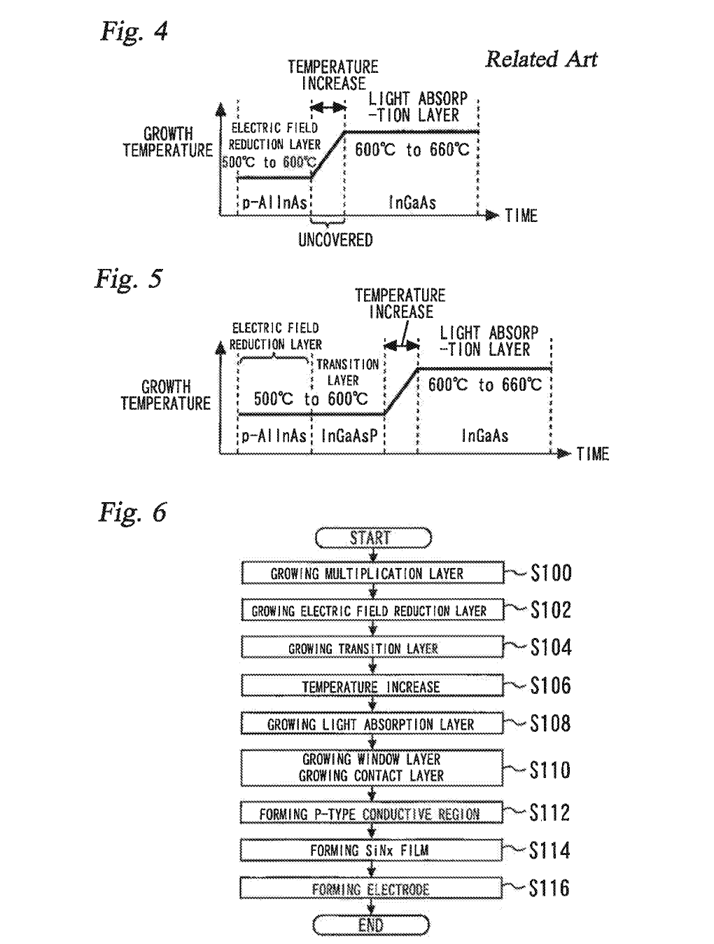

A method of manufacturing the avalanche photodiode 20 in accordance with the present embodiment will be described with reference to FIGS. 4 to 6. FIG. 4 is a diagram showing a growth sequence of a comparative example avalanche photodiode having a carbon-doped AlInAs electric field reduction layer. FIG. 5 is a diagram showing a growth sequence of an avalanche photodiode having a carbon-doped AlInAs electric field reduction layer in accordance with the present embodiment. This avalanche photodiode has a configuration similar to that shown in FIG. 4, but additionally includes InGaAsP transition layers; that is, this avalanche photodiode corresponds to the avalanche photodiode 20 of the present embodiment. FIG. 6 is a flowchart showing a method of manufacturing an avalanche photodiode in accordance with the present embodiment.

In the manufacture of the avalanche photodiode of the present embodiment, metal organic vapor phase epitaxy (MOVPE) or molecular beam epitaxy (MBE), etc. may be used to grow each semiconductor layer on the n-type InP substrate 2. In accordance with the present embodiment, each semiconductor layer is grown by MOVPE using the following sequential steps.

(Step S100)

In the manufacturing method of the present embodiment, first, the n-type InP buffer layer 3 having a carrier concentration of 1×10¹⁸-5×10¹⁸ cm⁻³ is grown at a growth temperature of 630° C. by MOVPE to a thickness of 0.1-1 μm on the n-type InP substrate 2 mounted within a chamber. The i-type AlInAs avalanche multiplication layer 4 is then grown (Step S100).

(Step S102)

Next, the growth temperature in the chamber is decreased to 580° C. The sequence shown in FIG. 5 starts after the growth temperature has been decreased to 580° C. The p-type AlInAs electric field reduction layer 5 is then grown on the i-type AlInAs avalanche multiplication layer 4. The growth temperature for the p-type AlInAs electric field reduction layer 5 is within the range of from 550° C. to 600° C., inclusive. The p-type AlInAs electric field reduction layer 5 is made of carbon-doped AlInAs. Thus, the p-type AlInAs electric field reduction layer 5 is doped with carbon, which has a low diffusivity, and grown at a relatively low temperature in this step so as to have the desired adequate carrier concentration. It should be noted that the first, second, and third transition layers 6, 7, and 8 have a composition of In₁₋ₓGaₓAs_{y}P_{1-y}, where, preferably, 0.024≦x≦0.483 and 0.053≦y≦0.928. Further, the first, second, and third transition layers 6, 7, and 8 may have a composition including In, Ga, As, P, and Al.

(Step S104)

The first, second, and third transition layers 6, 7, and 8 of n-type InGaAsP are sequentially grown to cover the top surface of the p-type AlInAs electric field reduction layer 5. It should be noted that the first, second, and third transition layers 6, 7, and 8 are grown at a lower temperature than the n⁻-type InGaAs light absorption layer 9. In the manufacturing method of the present embodiment, the first, second, and third transition layers 6, 7, and 8 are grown at substantially the same temperature as the p-type AlInAs electric field reduction layer 5, thereby avoiding thermal damage to the p-type AlInAs electric field reduction layer 5 during the formation of the first, second, and third transition layers 6, 7, and 8 during which the electric field reduction layer 5 is exposed. It should be noted that although in the growth sequence shown in FIG. 5 the p-type AlInAs electric field reduction layer 5 and the first, second, and third transition layers 6, 7, and 8 are grown at a substantially constant temperature, the present invention is not limited to this growth method. The second and third transition layers 7 and 8, which are grown after the growth of the first transition layer 6, may be grown at a higher temperature than the first transition layer 6 if the first transition layer 6 completely covers and thereby protects the p-type AlInAs electric field reduction layer 5 from thermal damage.

(Step S106)

In the method of the present embodiment, the temperature of the growth process is increased after all three transition layers have been formed to cover the top surface of the p-type AlInAs electric field reduction layer 5 (that is, after the electric field reduction layer 5 is covered by the third n⁻-type InGaAsP transition layer 8, which is the topmost one of the three transition layers). It should be noted, however, that the present invention is not limited to this method, as described above in connection with Step S104. The temperature of the growth process may be increased immediately after the p-type AlInAs electric field reduction layer 5 is covered by the first n⁻-type InGaAsP transition layer 6 if the first n⁻-type InGaAsP transition layer 6 completely covers and thereby protects the p-type AlInAs electric field reduction layer 5 from thermal damage.

(Step S108)

The n⁻-type InGaAs light absorption layer 9 is then grown. Specifically, in the method of the present embodiment, the n⁻-type InGaAs light absorption layer 9 is grown after the temperature of the growth process is increased in Step S106 to 630° C., which is higher than the temperature at which the p-type AlInAs electric field reduction layer 5 is grown. The n⁻-type InGaAs light absorption layer 9 is grown on the third n⁻-type InGaAsP transition layer 8, which is the topmost one of the three transition layers. The growth temperature of the n⁻-type InGaAs light absorption layer 9 is within the range of from 600° C. to 660° C., inclusive. Thus, in this step, the n⁻-type InGaAs light absorption layer 9 is grown at relatively high temperature so as to have good crystal quality.

FIG. 5 is a diagram showing a growth sequence of an avalanche photodiode having a carbon-doped AlInAs electric field reduction layer in accordance with the present embodiment. This avalanche photodiode has a configuration similar to that shown in FIG. 4, but additionally includes InGaAsP transition layers; that is, this avalanche photodiode corresponds to the avalanche photodiode 20 of the present embodiment. Since InGaAsP can be grown at a lower temperature than AlGaInAs, the InGaAsP transition layers can be grown at substantially the same temperature as the AlInAs electric field reduction layer so as to have good crystal quality. The InGaAsP transition layers thus grown cover the entire surface of the AlInAs electric field reduction layer and hence protect it when the temperature of the growth process (for growing the avalanche photodiode structure) has been increased to the temperature at which the InGaAs light absorption layer is grown. It should be noted that it is very difficult to grow a transition layer of AlGaInAs with good crystal quality at low temperature, since the AlGaInAs transition layer will be contaminated with oxygen, etc. during its growth process, meaning that the growth of an AlGaInAs transition layer requires accurate crystal growth control. On the other hand, a transition layer of InGaAsP can be grown immediately after the growth of the carbon-doped AlInAs electric field reduction layer (which must be grown at low temperature), resulting in simple growth control.

(Step S110)

Next, an n⁻-type InP window layer and a p-type InGaAs contact layer, which will become the n⁻-type InP window layer 10 and the p-type InGaAs contact layer 11, respectively, are grown.

(Step S112)

A p-type conductive region forming step is then performed. Specifically, first, an SiOx film is formed on the contact layer and a circular opening having a diameter of 25 μm is formed in the SiOx film. The p-type conductive region 14 is then formed, by Zn selective thermal diffusion, in the circular portion of the window layer that is not covered by the SiOx film, which serves as a mask. (The remaining portion of the window layer constitutes the n⁻-type InP window layer 10.) The contact layer is then etched so as to form the p-type InGaAs contact layer 11, which has an annular shape and an annular width of 5 μm, on the p-type conductive region 14.

(Step S114)

The SiNx surface protection antireflection film 13 is then formed by vapor deposition.

(Step S116)

An electrode forming step is then performed. Specifically, first, the SiNx surface protection antireflection film 13 is removed from on top of the p-type InGaAs contact layer 11. The p-electrode 12 is then formed on the p-type InGaAs contact layer 11 using AnZn material. Lastly, the surface of the n-type InP substrate 2 opposite that on which the n-type InP buffer layer 3 lies is polished, and the n-electrode 1 is formed on the polished surface using AuGeNi material.

The manufacturing method described above can be used to manufacture an avalanche photodiode having good crystal growth interfaces by minimizing thermal damage due to an increase in the temperature of the growth process.

Advantages of the present embodiment will be described in comparison with the comparative example shown in FIG. 4. FIG. 4 shows a growth sequence of a comparative example avalanche photodiode provided with a carbon-doped AlInAs electric field reduction layer. In this sequence, immediately after the carbon-doped AlInAs electric field reduction layer is grown at relatively low temperature, the temperature of the growth process is increased to the temperature at which the InGaAs light absorption layer is grown. This causes thermal damage and resulting defects to the exposed surface of the carbon-doped AlInAs electric field reduction layer, making it difficult to form a good interface between the AlInAs electric field reduction layer and the InGaAs light absorption layer subsequently grown on the electric field reduction layer. Degradation of the interface between the AlInAs electric field reduction layer and the InGaAs light absorption layer may adversely affect the device characteristics such as dark current. In the manufacturing method of the present embodiment, on the other hand, the surface of the p-type AlInAs electric field reduction layer 5 is covered with the first, second, and third transition layers 6, 7, and 8 and hence is not exposed when the InGaAs light absorption layer 9 is grown (see FIG. 5), thereby preventing thermal damage to the surface of the p-type AlInAs electric field reduction layer 5.

An avalanche photodiode having an AlInAs electron multiplication layer, such as the avalanche photodiode 20, typically has an electric field reduction layer of InP or AlInAs doped with a p-type dopant such as Zn, Mg, or Be, etc. A known technique for reducing the diffusion of p-type dopant from the p-type electric field reduction layer to the multiplication layer or the light absorption layer in such an avalanche photodiode is to configure the electric field reduction layer as an AlInAs layer doped with carbon, which has low diffusivity. It should be noted that the carbon-doped AlInAs electric field reduction layer is grown in crystalline form at relatively low temperature so as to have the desired adequate p-type carrier concentration. The InGaAs light absorption layer, on the other hand, must be grown at relatively high temperature so as to have good crystal quality. That is, the growth temperature of the InGaAs light absorption layer is higher than that of the carbon-doped AlInAs electric field reduction layer. Since the light absorption layer is grown after the growth of the electric field reduction layer, the temperature of the growth process must be increased when switching from the growth of the electric field reduction layer to that of the light absorption layer. It has been found, however, that this increase in the process temperature causes thermal damage to the surface of the electric field reduction layer, resulting in detects in the interface between the electric field reduction layer and the light absorption layer subsequently formed on the electric field reduction layer.

Further, as described with reference to FIGS. 2 and 3, the InGaAs light absorption layer and the carbon-doped AlInAs electric reduction layer have a large bandgap energy difference. This prevents movement of carriers generated in the avalanche photodiode by incident light during the operation of the avalanche photodiode.

On the other hand, in addition to the advantage that its electric field reduction layer is doped with carbon (which has low diffusivity), the avalanche photodiode 20 of the present embodiment has good crystal growth interfaces since it is manufactured while minimizing thermal damage due to an increase in the temperature of the growth process. The configuration of the avalanche photodiode 20 also enables it to achieve high speed response.

Variations of Embodiment

Although the present embodiment has been described in connection with an avalanche photodiode having a carbon-doped AlInAs electric field reduction layer, it is to be understood that the present embodiment may be applied to avalanche photodiodes having an AlInAs electric field reduction layer doped with a different p-type dopant such as Zn, Mg, or Be instead of carbon. Further, the electric field reduction layer may be made of any suitable material (such as InGaAsP or AlGaInAs) that has a bandgap similar to that of InP and that is lattice-matched to InP.

Further, although the present embodiment has been described in connection with an avalanche photodiode having three n⁻-type InGaAsP transition layers, it is to be understood that the present embodiment may be applied to an avalanche photodiode having four or more transition layers, and the bandgaps of these transition layers may be decreased stepwise with increasing distance from the electric field reduction layer and decreasing distance from the light absorption layer. This further reduces the differences in valence band energy level between the electric field reduction layer, the transition layers, and the light absorption layer, allowing the avalanche photodiode to achieve higher speed response to light. Further, the bandgaps of the transition layers may be decreased continuously, instead of stepwise, with increasing distance from the electric field reduction layer and decreasing distance from the light absorption layer. Further, the transition layers are not limited to InGaAsP, but may be made of any suitable material having a bandgap intermediate between those of AlInAs and InGaAs; for example, the transition layers may have a composition including Al, Ga, In, As, and P.

Although in the present embodiment the p-type conductive region 14 is formed in the n⁻-type InP window layer 10 by Zn selective thermal diffusion, it is to be understood that in other embodiments other suitable types of atoms may be used to form a p-type conductive region in the window layer 10.

Although the above-described avalanche photodiode of the present embodiment has a top-illuminated structure in which light to be detected is directed to enter the p-type conductive region 14 from the p-electrode 12 side of the avalanche photodiode, it is to be understood that the present embodiment may be applied to an avalanche photodiode having a bottom-illuminated structure in which light to be detected is directed to enter the avalanche photodiode from the n-type InP substrate 2 side.

Although in the present embodiment the avalanche multiplication layer of the avalanche photodiode is an i-type AlInAs avalanche multiplication layer, it is to be understood that in other embodiments the avalanche multiplication layer may be formed of other suitable semiconductor material which is lattice-matched to InP and in which the electron ionization rate is higher than the hole ionization rate. That is, the avalanche multiplication layer may be formed of InGaAsP, or a superlattice of AlInAs/AlGaInAs or AlInAs/InGaAsP. Further, although the present embodiment has been described in connection with a multiplication layer having a high electron ionization rate, it is to be understood that the present embodiment may be applied to a multiplication layer having a high hole ionization rate, in which case the conductivity type of each layer and region of the avalanche photodiode may be reversed from those noted above so as to achieve the same advantages as described above in connection with the present embodiment.

The features and advantages of the present invention may be summarized as follows: The present invention provides an improved avalanche photodiode and a method of manufacture thereof wherein the avalanche photodiode is manufactured while minimizing thermal damage due to an increase in the temperature of the growth process so that the avalanche photodiode has good crystal growth interfaces.

1. A method of manufacturing an avalanche photodiode, comprising:
growing a multiplication layer on a semiconductor substrate;
growing an electric field reduction layer on the multiplication layer at a first temperature;
growing a transition layer having a bandgap at a second temperature so as to cover a top surface of the electric field reduction layer; and
after covering the top surface of the electric field reduction layer by with the transition layer, growing a light absorption layer having a bandgap on the transition layer at a third temperature, higher than the first temperature at which the electric field reduction layer is grown, wherein
the second temperature at which the transition layer is grown is lower than the third temperature at which the light absorption layer is grown, and
the transition layer is composed of a semiconductor material having higher resistance to surface defects than the electric field reduction layer at temperatures higher than the first temperature at which the electric field reduction layer is grown.

2. The method according to claim 1, wherein the transition layer includes one or a plurality of semiconductor layers, and a the bandgap of the transition layer has a magnitude that approaches magnitude of the bandgap of the light absorption layer with increasing distance from the electric field reduction layer and decreasing distance from the light absorption layer.

3. The method according to claim 1, wherein the electric field reduction layer is composed of AlInAs doped with carbon.

4. The method according to claim 1, wherein the transition layer is an InGaAsP layer, and the light absorption layer is an InGaAs layer.

5. The method according to claim 1, wherein the first temperature at which the electric field reduction layer is grown is within a range from 550° C. to 600° C., inclusive.

6. The method according to claim 1, wherein the third temperature at which the light absorption layer is grown is within a range from 600° C. to 660° C., inclusive.

7. The method according to claim 1, wherein the transition layer has a composition of In₁₋ₓGaₓAs_{y}P_{1-y}, where 0.024≦x≦0.483 and 0.053≦y≦0.928.

8. The method according to claim 1, wherein the transition layer is a semiconductor layer having a composition including In, Ga, As, P, and Al.

9. An avalanche photodiode comprising:
a semiconductor substrate;
a multiplication layer on the semiconductor substrate;
an electric field reduction layer having a bandgap and disposed on the multiplication layer;
a transition layer covering a top surface of the electric field reduction layer; and
a light absorption layers having a bandgap and disposed on the transition layer and grown at a temperature, wherein
the transition layer has a bandgap between the bandgap of the electric field reduction layer and the bandgap of the light absorption layer,
the transition layer is composed of a semiconductor material that grows at a temperature lower than the temperature at which the light absorption layer is grown, and
the transition layer is composed of a semiconductor material having higher resistance to surface defects than the electric field reduction layer at the temperature at which the light absorption layer is grown.

10. The avalanche photodiode according to claim 9, wherein the transition layer includes one or a plurality of semiconductor layers, and of the bandgap of the transition layer has a magnitude that approaches magnitude of the bandgap of the light absorption layer with increasing distance from the electric field reduction layer and decreasing distance from the light absorption layer.

11. The avalanche photodiode according to claim 9, wherein the electric field reduction layer is composed of AlInAs doped with carbon.

12. The avalanche photodiode according to claim 9, wherein the electric field reduction layer is one of an AlInAs layer, an InGaAsP layer, and an AlGaInAs layer.

13. The avalanche photodiode according to claim 9, wherein the light absorption layer is an InGaAs layer.

14. The avalanche photodiode according to claim 9, wherein the transition layer has a composition of In₁₋ₓGaₓAs_{y}P_{1-y}, where 0.024≦x≦0.483 and 0.053≦y≦0.928.

15. The avalanche photodiode according to claim 9, wherein the transition layer is a semiconductor layer having a composition including In, Ga, As, P, and Al.
